(19) United States
(12) Patent Application Publication
(10) Pub. No.: US 2023/0420535 A1
(43) Pub. Date: Dec. 28, 2023

(54) SEMICONDUCTOR DEVICES

(71) Applicant: Samsung Electronics Co., Ltd., Suwon-si (KR)

(72) Inventors: Kanghun Moon, Suwon-si (KR); Kyungho Kim, Suwon-si (KR); Kihwan Kim, Suwon-si (KR); Choeun Lee, Suwon-si (KR); Yonguk Jeon, Suwon-si (KR)

(73) Assignee: Samsung Electronics Co, Ltd., Suwon-si (KR)

(21) Appl. No.: 18/195,074

(22) Filed: May 9, 2023

(30) Foreign Application Priority Data
Jun. 23, 2022 (KR) 10-2022-0076928

(51) Int. Cl. H01L 29/423; H01L 29/66; H01L 29/417; H01L 29/786; H01L 29/06; H01L 29/775

(52) U.S. Cl. CPC H01L 29/42392; H01L 29/66545; H01L 29/41775; H01L 29/78696; H01L 29/0673; H01L 29/775

(57) ABSTRACT

A semiconductor device includes: an active region on a substrate extending in a first direction; a plurality of semiconductor layers spaced apart from each in a vertical direction on the active region, the plurality of semiconductor layers including lower and upper semiconductor layers; a gate structure on the substrate extending in a second direction to intersect the active region and the plurality of semiconductor layers; and a source/drain region on the active region and contacting the plurality of semiconductor layers. The source/drain region includes first epitaxial layers, including first layers on a side surface of the lower semiconductor layer and a second layer provided on and contacting the active region, and a second epitaxial layer contacts a side surface of the upper semiconductor layer in the first direction, and the first layer is between the second epitaxial layer and the side surface of the lower semiconductor layer.

### CROSS-REFERENCE TO RELATED APPLICATION(S)

This application claims priority to Korean Patent Application No. 10-2022-0076928 filed on Jun. 23, 2022 in the Korean Intellectual Property Office, the disclosure of which is incorporated herein by reference in its entirety.

### BACKGROUND

The present disclosure relates to semiconductor devices.

As demand for high performance, high speed, and/or multifunctionality in semiconductor devices increases, the degree of integration of semiconductor devices has increased. When a semiconductor device with high integration is fabricated, the semiconductor device may include patterns having fine widths or fine spacings therebetween. Moreover, to overcome limitations of operating characteristics caused by a reduction in size of a planar metal oxide semiconductor FET (MOSFET), efforts have been made to develop a semiconductor device including a FinFET having a channel with a three-dimensional structure.

### SUMMARY

One or more example embodiments provide a semiconductor device having improved electrical characteristics.

According to an aspect of an example embodiment, a semiconductor device includes: a substrate; an active region extending in a first direction on the substrate; a plurality of semiconductor layers spaced apart from each other in a vertical direction on the active region, the plurality of semiconductor layers including a lower semiconductor layer and an upper semiconductor layer on the lower semiconductor layer; a gate structure extending in a second direction on the substrate and intersecting the active region and the plurality of semiconductor layers, the gate structure surrounding the plurality of semiconductor layers; and a source/drain region provided on the active region on at least one side adjacent to the gate structure and contacting the plurality of semiconductor layers, wherein the source/drain region includes first epitaxial layers and a second epitaxial layer, wherein the first epitaxial layers include a first layer contacting a side surface of the lower semiconductor layer in the first direction, and a second layer provided on and contacting the active region, the second epitaxial layer contacts a side surface of the upper semiconductor layer in the first direction, and the first layer is between the second epitaxial layer and the side surface of the lower semiconductor layer.

According to an aspect of an example embodiment, a semiconductor device includes: a substrate; an active region extending in a first direction on the substrate; a plurality of semiconductor layers spaced apart from each other in a vertical direction on the active region; a gate structure extending in a second direction on the substrate and intersecting the active region and the plurality of semiconductor layers, the gate structure surrounding the plurality of semiconductor layers; inner spacer layers provided on opposite sides adjacent to the gate structure in the first direction on a lower surface of each of the plurality of semiconductor layers and vertically overlapping the plurality of semiconductor layers; and a source/drain region provided on the active region on at least one side adjacent to the gate structure and contacting the plurality of semiconductor layers, wherein the plurality of semiconductor layers include a lower semiconductor layer and an upper semiconductor layer provided on the lower semiconductor layer, and the source/drain region includes: a first epitaxial layer provided on a side surface of the lower semiconductor layer and at a level lower than a level of the upper semiconductor layer; and a second epitaxial layer having a composition that is different from a composition of the first epitaxial layer, extending upwardly on a side surface of the upper semiconductor layer and covering the first epitaxial layer.

According to an aspect of an example embodiment, a semiconductor device includes: a substrate; an active region extending in a first direction on the substrate; a plurality of semiconductor layers spaced apart from each other in a vertical direction on the active region, the plurality of semiconductor layers including a lower semiconductor layer and an upper semiconductor layer; a gate structure extending in a second direction on the substrate and intersecting the active region and the plurality of semiconductor layers, the gate structure surrounding the plurality of semiconductor layers; and a source/drain region provided on the active region on at least one side adjacent to the gate structure and contacting the plurality of semiconductor layers, wherein the upper semiconductor layer has a central region and an outer region on an outer side of the central region in the first direction, and the outer region is different from the central region.

### BRIEF DESCRIPTION OF DRAWINGS

The above and other aspects, features, and advantages of the present disclosure will be more apparent from the following detailed description of example embodiments, taken in conjunction with the accompanying drawings, in which:

FIG. 1 is a plan view illustrating a semiconductor device according to example embodiments;

FIG. 2 is a cross-sectional view illustrating a semiconductor device according to example embodiments;

FIG. 3 is a partially enlarged view illustrating a portion of a semiconductor device according to example embodiments;

FIG. 4 is a diagram illustrating a distribution of an impurity concentration in a source/drain region in a semiconductor device according to example embodiments;

FIGS. 5A and 5B are partially enlarged views illustrating a portion of a semiconductor device according to example embodiments;

FIG. 6 is a partially enlarged view illustrating a portion of a semiconductor device according to example embodiments;

FIG. 7 is a partially enlarged view illustrating a portion of a semiconductor device according to example embodiments;

FIG. 8 is a partially enlarged view illustrating a portion of a semiconductor device according to example embodiments;

FIG. 9 is a partially enlarged view illustrating a portion of a semiconductor device according to example embodiments;

FIGS. 10A to 10K are diagrams illustrating a process sequence of a method of fabricating a semiconductor device according to example embodiments;

FIG. 11 is a block diagram illustrating an electronic apparatus including a semiconductor device according to example embodiments; and

FIG. 12 is a schematic diagram illustrating a system including a semiconductor device according to example embodiments.

### DETAILED DESCRIPTION

Hereinafter, example embodiments will be described with reference to the accompanying drawings.

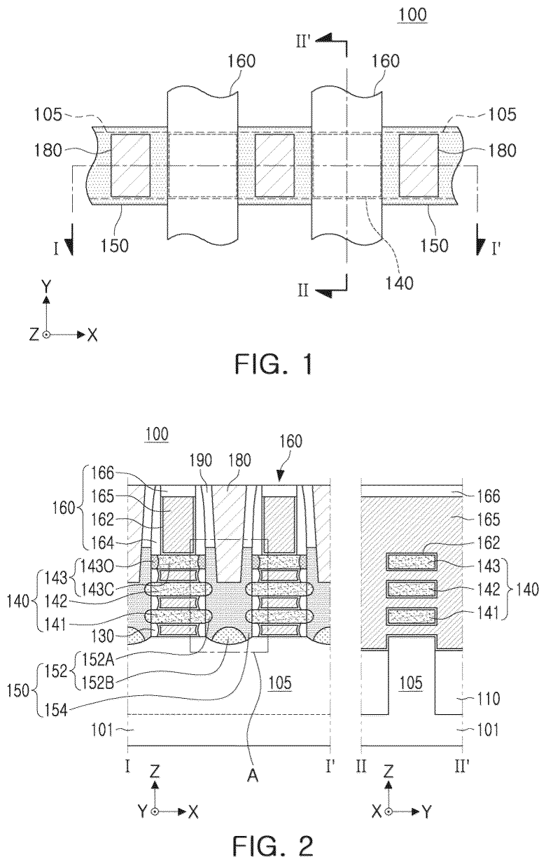

FIG. 1 is a plan view illustrating a semiconductor device according to example embodiments.

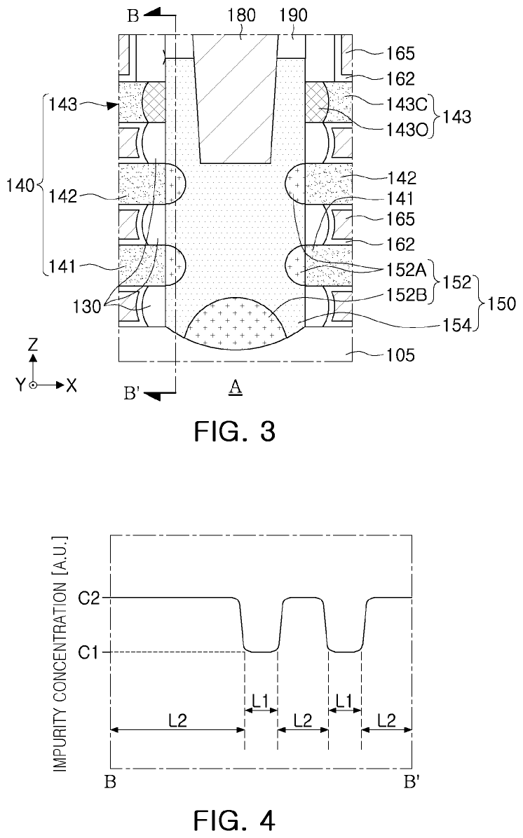

FIG. 2 is a cross-sectional view illustrating a semiconductor device according to example embodiments. FIG. 2 illustrates cross-sections of the semiconductor device of FIG. 1, taken along lines I-I′ and II-IF′. For ease of description, only major components of the semiconductor device are illustrated in FIGS. 1 and 2.

Referring to FIG. 1 and FIG. 2, a semiconductor device 100 may include a substrate 101, an active region 105 on substrate 101, channel structures 140 including a plurality of semiconductor layers 141, 142, and 143 spaced apart from each other vertically on the active region 105, source/drain regions 150 contacting the plurality of semiconductor layers 141, 142, and 143, gate structures 160 extending to intersect the active region 105, and contact plugs 180 connected to the source/drain regions 150. The semiconductor device 100 may further include isolation layers 110, inner spacer layers 130, and an interlayer insulating layer 190. The gate structure 160 may include a gate dielectric layer 162, a gate electrode 165, spacer layers 164, and a gate capping layer 166.

In the semiconductor device 100, the active region 105 may have a fin structure and the gate electrode 165 may be disposed between the active region 105 and the channel structures 140, between the plurality of channel layers 141, 142, and 143 of the channel structures 140, and on the channel structures 140. Accordingly, the semiconductor device 100 may include gate-all-around type field effect transistors formed by the channel structures 140, the source/drain regions 150, and the gate structures 160. The transistors may be, for example, NMOS transistors.

The substrate 101 may have an upper surface extending in an X-direction and a Y-direction. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon-on-insulator (SOI) layer, a semiconductor-on-insulator (SeOI) layer, or the like.

The isolation layers 110 may define active regions 105 in the substrate 101. The isolation layer 110 may be formed by, for example, a shallow trench isolation (STI) process. In example embodiments, the isolation layer 110 may further include a region extending relatively deeper while having a step in a lower portion of the substrate 101. The isolation layer 110 may partially expose an upper portion of the active region 105. In example embodiments, the isolation layer 110 may also have a curved upper surface having a level increased in a direction toward the active region 105. The isolation layer 110 may be formed of an insulating material. The isolation layer 110 may be formed of, for example, an oxide, a nitride, or a combination thereof.

The active region 105 may be defined by the isolation layer 110 in the substrate 101 and may extend in a first direction, for example, in an X-direction. The active region 105 may have a structure protruding from the substrate 101. An upper end of the active region 105 may protrude from upper surfaces of the isolation layers 110 to a predetermined height. The active region 105 may be formed as a portion of the substrate 101 or may include an epitaxial layer grown from the substrate 101. A portion of the active region 105 on the substrate 101 may be recessed on opposite sides adjacent to the gate structures 160, and source/drain regions 150 may be disposed on the recessed portions of the active region 105. The active region 105 may include impurities or doping regions including impurities.

The channel structure 140 may include two or more channel layers on the active region 105 and spaced apart from each other in a direction, perpendicular to the upper surface of the active region 105, for example, in a Z-direction. The plurality of channel layers may include first to third semiconductor layers 141, 142, and 143 stacked sequentially. The first to third semiconductor layers 141, 142, and 143 may be connected to the source/drain regions 150, and may be spaced apart from the upper surface of the active region 105. Each of the first to third semiconductor layers 141, 142, and 143 may have a width the same as or similar to a width of the active region 105 in the Y-direction, and may have a width the same as or similar to a width of the gate structure 160 in the X-direction. According to example embodiments, the first to third semiconductor layers 141, 142, and 143 may have a reduced width in such a manner that side surfaces of the first to third semiconductor layers 141, 142, and 143 are disposed below the gate structure 160 in the X-direction.

The first to third channel layers 141, 142, and 143 may be formed of a semiconductor material, and may include at least one of, for example, silicon (Si), silicon-germanium (SiGe), or germanium (Ge). The first to third channel layers 141, 142, and 143 may be formed of, for example, the same material as the substrate 101. According to example embodiments, the first to third channel layers 141, 142, and 143 may include an impurity region disposed in a region adjacent to the source/drain region 150. The number and shape of the channel layers 141, 142, and 143, constituting a single channel structure 140, may vary according to example embodiments. For example, according to example embodiments, the channel structure 140 may further include a channel layer disposed on the upper surface of the active region 105.

In the present example embodiment, the third semiconductor layer 143 may be referred to as an “upper semiconductor layer” or “uppermost semiconductor layer,” and each of the first and second semiconductor layers 141 and 142 may be referred to as a “lower semiconductor layer.”

In example embodiments, the third semiconductor layer 143, an upper semiconductor layer, may include a central region 143C and an outer region 143O disposed on an outer side of the central region 143C in the X-direction. The outer region 143O may have a convex shape toward the central region 143C, but the shape of the outer region 143O is not limited thereto.

The outer region 143O of the third semiconductor layer 143 may have a distinctive boundary with the central region 143C of the third semiconductor layer 143.

In example embodiments, the outer region 143O may have a composition, different from a composition of the central region 143C. In example embodiments, the outer region 143O may include impurities, different from impurities included in the central region 143C. For example, the central region 143C may not include impurities, and the outer region 143O may include impurities. In other example embodiments, the central region 143C may include impurities and the outer region 143O may include impurities that are different than the impurities included in the central region 143C. The impurities of the outer region 143O may include at least one of silicon (Si), phosphorus (P), and arsenic (As).

In example embodiments, the outer region 143O may have crystallinity, different from crystallinity of the central region 143C. For example, the crystallinity of a material of the outer region 143O may be lower than the crystallinity of a material of the central region 143C. For example, the material of the central region 143C may include single-crystalline silicon and the material of the outer region 143O may include amorphous silicon. According to example embodiments, the outer region 143O may have a crystal structure close to a single-crystalline silicon. Even in this case, the material of the outer region 143O may have a crystal structure having crystallinity that is lower than the crystallinity of the material of the central region 143C.

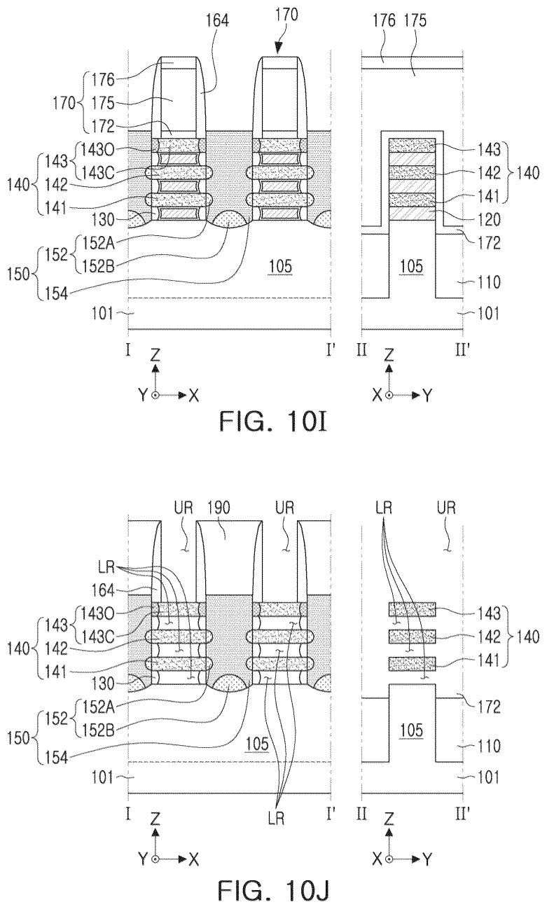

According to example embodiments, each of the first and second semiconductor layers 141 and 142, the lower semiconductor layers, may include a central region and an outer region disposed on an outer side of the central region. The outer region of each of the first and second semiconductor layers 141 and 142 and the outer region and the outer region 143O of the third semiconductor layer 143 may be different in impurities, crystallinity, or size, and thus may have different structures. This may be because the outer region 143O of the third semiconductor layer 143 is a region formed by an ion implantation process of FIG. 10G, whereas the outer region of each of the first and second semiconductor layers 141 and 142 is a layer formed by diffusing the impurities of the first epitaxial layer 152.

The inner spacer layers 130 may be disposed between the channel structures 140. The inner spacer layers 130 may be disposed side by side with the gate electrode 165 on opposite sides adjacent to the gate structure 160 in one direction, for example, in the X-direction. The inner spacer layers 130 may vertically overlap the plurality of semiconductor layers 141, 142, and 143. The gate electrode 165 may be spaced apart from the source/drain regions 150 by the inner spacer layers 130 to be electrically isolated from each other, below the third semiconductor layer 143. The inner spacer layers 130 may have a shape in which a side surface facing the gate electrode 165 is convexly rounded inwardly of the gate electrode 165, but example embodiments are not limited thereto. The inner spacer layers 130 may have outer surfaces, substantially coplanar with the outer surfaces of the plurality of semiconductor layers 141, 142, and 143. The inner spacer layers 130 may be formed of an oxide, a nitride, or an oxynitride. For example, the inner spacer layers 130 may include a low-κ dielectric material.

The source/drain regions 150 may be disposed on the active region 105 on opposite sides adjacent to the channel structure 140. The source/drain region 150 may include first epitaxial layers 152, disposed on the active region 105 on a side surface of each of the first and second semiconductor layers 141 and 142 of the channel structure 140 and on a lower end of the source/drain region 150, and a second epitaxial layer 154 filling a space between the first epitaxial layers 152. Both the first epitaxial layers 152 and the second epitaxial layer 154 may be semiconductor layers including silicon (Si), and may include impurities of different types and/or concentrations.

The first epitaxial layer 152 may be disposed on a level that is lower than a level of the third semiconductor layer 143, and the second epitaxial layer 154 may extend upwardly of a side surface of the third semiconductor layer 143 while covering the first epitaxial layer 152.

The first epitaxial layers 152 may include first layers 152A, disposed on side surfaces of the first and second semiconductor layers 141 and 142, and second layer 152B disposed on an upper surface of the active region 105.

The first layers 152A may be disposed on opposite side surfaces of the first and second semiconductor layers 141 and 142 in the X-direction. T the first layers 152A may contact side surfaces of the first and second semiconductor layers 141 and 142. The first layers 152A may be disposed on opposite side surfaces of the channel structure 140 to effectively suppress a short-channel effect caused by diffusion of impurities in the second epitaxial layer 154. The first layers 152A may be separated from each other between the first to third semiconductor layers 141, 142, and 143 which are disposed sequentially along the vertical Z-direction. The first layers 152A may be spaced apart from the second layer 152B. In addition, the first layers 152A may be formed to protrude toward the second epitaxial layer 154 from a side surface, a substantially coplanar surface formed by the inner spacer layers 130 and the first to third semiconductor layers 141, 142, and 143. Accordingly, the second epitaxial layer 154 may be interposed between the first layers 152A which are spaced apart from each other in the Z-direction. Also, the second epitaxial layer 154 may be interposed between the first layers 152A which are also spaced apart from each other in a single source/drain region 150 in the X-direction. The first epitaxial layers 152 may be disposed to overlap at least a portion of the second epitaxial layer 154 and to not overlap the inner spacer layers 130 in plan view.

The second layer 152B may be disposed on at least a portion of the upper surface of the active region 105 on a lower end thereof. For example, the second layer 152B may be disposed in a central region in the X-direction. The second layer 152B may contact the upper surface of the active region 105. The second layer 152B may have a maximum thickness, higher than a thickness of each of the first layers 152A. In addition, the second layer 152B may have a shape, in which a width of an upper portion is narrower than a width of a lower portion, and may have an upwardly convex shape. A lower surface of the source/drain region 150 may have various shapes, such as a shape having different degrees of convexity or a planar shape, according to example embodiments. Accordingly, the shape of the second layer 152B may vary according to example embodiments.

The first epitaxial layer 152 may be a region including impurities at a concentration, higher than a concentration of impurities included in the active region 105. The first epitaxial layers 152 may be epitaxially grown from the first and second semiconductor layers 141 and 142 and the active region 105. For example, the first epitaxial layer 152 may include N-type impurities such as arsenic (As) and/or phosphorus (P). The first epitaxial layer 152 may be, for example, a SiAs layer, a SiP layer, a SiPC layer, a SiC layer, a SiPAs layer, or a SiGeP layer.

The second epitaxial layer 154 may be disposed to completely fill a region between adjacent channel structures 140, and may be disposed to surround a surface on which the first epitaxial layer 152 does not contact the channel structure 140 or the active region 105 and to cover side surfaces of the inner spacer layers 130. The second epitaxial layer 154 may be disposed to fill a space between the first layers 152A of the first epitaxial layers 152, spaced apart from each other vertically. Accordingly, at least a portion of the second epitaxial layer 154 may overlap each of the first layers 152A and the second layer 152B of the first epitaxial layers 152 in the vertical Z-direction.

The second epitaxial layer 154 may cover opposite side surfaces of the third semiconductor layer 143. The second epitaxial layer 154 may contact a side surface of the third semiconductor layer 143. For example, the second epitaxial layer 154 may contact the outer region 143O of the third semiconductor layer 143. The second epitaxial layer 154 may include a portion extending from the side surface of the inner spacer layers 130 below the third semiconductor layer 143 to the side surface of the third semiconductor layer 143. The first epitaxial layers 152 may be disposed on the side surfaces of the first and second semiconductor layers 141 and 142, the lower semiconductor layers. In an example embodiment, the epitaxial layers 152 are not disposed on the side surface of the third semiconductor layer 143, the upper semiconductor layer, though example embodiments are not limited thereto.

The second epitaxial layer 154 may extend upwardly on a side surface of the third semiconductor layer 143 while covering the first epitaxial layer 152. For example, the second epitaxial layer 154 may cover a first side surface, formed by the inner spacer layers 130 and the third semiconductor layer 143, and a second side surface formed by the first layers 152A of the first epitaxial layers 152 protruding from the first and second semiconductor layers 141 and 142.

The first layers 152A may be disposed between the side surfaces of the first and second semiconductor layers 141 and 142, the lower semiconductor layers, and the second epitaxial layer 154.

The second epitaxial layer 154 may have a composition, different from a composition of the first epitaxial layers 152. For example, the second epitaxial layer 154 may be a region including impurities at a higher concentration than the first epitaxial layer 152. The second epitaxial layer 154 may be a layer epitaxially grown from the first epitaxial layer 152. The impurities of the second epitaxial layer 154 may be the same as or different from the impurities included in the first epitaxial layer 152 in either type or concentration. For example, the first epitaxial layer 152 may include first impurities having a first conductivity type at a first concentration, and the second epitaxial layer 154 may include the first impurities having the first conductivity type at a second concentration, higher than the first concentration or second impurities having the second conductivity type at the second concentration. For example, the second epitaxial layer 154 may be a SiP layer including phosphorus (P). In example embodiments, the first epitaxial layer 152 may be a SiP or SiAs epitaxial layer, and the second epitaxial layer 154 may be a SiP epitaxial layer.

As the third semiconductor layer 143, the upper semiconductor layer, has the outer region 143O different from the central region 143C, epitaxial growth of the first epitaxial layer 152 on the side surface of the third semiconductor layer 143 may be suppressed. Accordingly, a process defect caused by overgrowth of the second epitaxial layer 154, such as a defect in which an upper surface of the second epitaxial layer 154 has a non-uniform level, may be prevented and dispersion of the second epitaxial layer 154 may be improved.

A portion of the impurities of the second epitaxial layer 154 may diffuse into an adjacent first epitaxial layer 152 to be included even in the first epitaxial layer 152 at a lower concentration than that in the first epitaxial layer 152. In addition, a portion of the impurities of the first epitaxial layer 152 may diffuse into an adjacent second epitaxial layer 154 to be included even in the second epitaxial layer 154 at a lower concentration than in the first epitaxial layer 152.

The gate structure 160 may be disposed on the active region 105 and the channel structures 140 and may extend in the second direction, for example, in the Y-direction, to intersect the active region 105 and the channel structures 140. Channel regions of transistors may be formed in the active region 105 and the channel structures 140 intersecting the gate structure 160. The gate structure 160 may include a gate electrode 165, a gate dielectric laser 162 between the gate electrode 165 and the plurality of channel layers 141, 142, and 143, a gate spacer layers 164 on side surfaces of the gate electrode 165, and a gate capping layer 166 on an upper surface of the gate electrode 165.

The gate dielectric layer 162 may be disposed between the active region 105 and the gate electrode 165 and between the channel structure 140 and the gate electrode 165, and may be disposed to cover at least a portion of surfaces of the gate electrode 165. For example, the gate dielectric layer 162 may be disposed to surround all surfaces of the gate electrode 165 except for an uppermost surface of the gate electrode 165. The gate dielectric layer 162 may extend between the gate electrode 165 and the gate spacer layers 164, but example embodiments are not limited thereto. The gate dielectric layer 162 may include an oxide, a nitride, and/or a high-K dielectric material. The high-K dielectric material may refer to a dielectric material having a higher dielectric constant than a silicon oxide (SiO₂). The high-K dielectric material may be at least one of, for example, an aluminum oxide (Al₂O₃), a tantalum oxide (Ta₂O₃), a titanium oxide (TiO₂), an yttrium oxide (Y₂O₃), a zirconium oxide (ZrO₂), a zirconium silicon oxide (ZrSiₓO_{y}), a hafnium oxide (HfO₂), a hafnium silicon oxide (HfSiₓO_{y}), a lanthanum oxide (La₂O₃), a lanthanum aluminum oxide (LaAlₓO_{y}), a lanthanum hafnium oxide (LaHfₓO_{y}), a hafnium aluminum oxide (HfAlₓO_{y}), and or a praseodymium oxide (Pr₂O₃).

The gate electrode 165 may be disposed to extend upwardly of the channel structure 140 while filling a space between the plurality of channel layers 141, 142, and 143 on the active region 105. The gate electrode 165 may be spaced apart from the plurality of channel layers 141, 142, and 143 by the gate dielectric layer 162. The gate electrode 165 may include a conductive material, for example, a metal nitride such as a titanium nitride (TiN), a tantalum nitride (TaN), or a tungsten nitride (WN), a metal material such as aluminum (Al), tungsten (W), or molybdenum (Mo), and/or a semiconductor material such as doped polysilicon. The gate electrode 165 may have a multilayer structure including two or more layers. The gate electrode 165 may be disposed to be divided by an additional separation portion between at least some adjacent transistors, depending on the configuration of the semiconductor device 100.

The gate spacer layers 164 may be disposed on opposite side surfaces of the gate electrode 165. The gate spacer layers 164 may insulate the source/drain regions 150 and the gate electrodes 165 from each other. In example embodiments, the gate spacer layers 164 may have a multilayer structure. The gate spacer layers 164 may be formed of an oxide, a nitride, or an oxynitride. For example, the gate spacer layers 164 may be formed of a low-κ dielectric material.

The gate capping layer 166 may be disposed on the gate electrode 165, and a lower surface and side surfaces of the gate capping layer 166 may be surrounded by the gate electrode 165 and the gate spacer layers 164, respectively.

The contact plug 180 may penetrate through the interlayer insulating layer 190 to be connected to the source/drain region 150, and may apply an electrical signal to the source/drain region 150. The contact plug 180 may be disposed on the source/drain region 150, as illustrated in FIG. 1. According to example embodiments, the contact plug 180 may also have a length, greater than a length of the source/drain region 150 in the Y-direction. The contact plug 180 may have an inclined side surface in which a width of a lower portion is narrower than a width of an upper portion due to an aspect ratio, but example embodiments are not limited thereto. The contact plug 180 may extend from the upper portion to be lower than, for example, the third channel layer 143. The contact plug 180 may be recessed to, for example, a height corresponding to the upper surface of the second channel layer 142, but example embodiments are not limited thereto. In example embodiments, the contact plug 180 may also be disposed to contact along an upper surface of the source/drain region 150 without recessing the source/drain region 150. The contact plug 180 may include, for example, a metal nitride such as a titanium nitride (TiN), a tantalum nitride (TaN), or a tungsten nitride (WN), and/or a metal such as aluminum (Al), tungsten (W), or molybdenum (Mo).

The interlayer insulating layer 190 may cover the source/drain regions 150 and the gate structures 160, and may be disposed to cover the isolation layer 110 in a region. The interlayer insulating layer 190 may include at least one of, for example, an oxide, a nitride, and an oxynitride, and may include a low-K dielectric material.

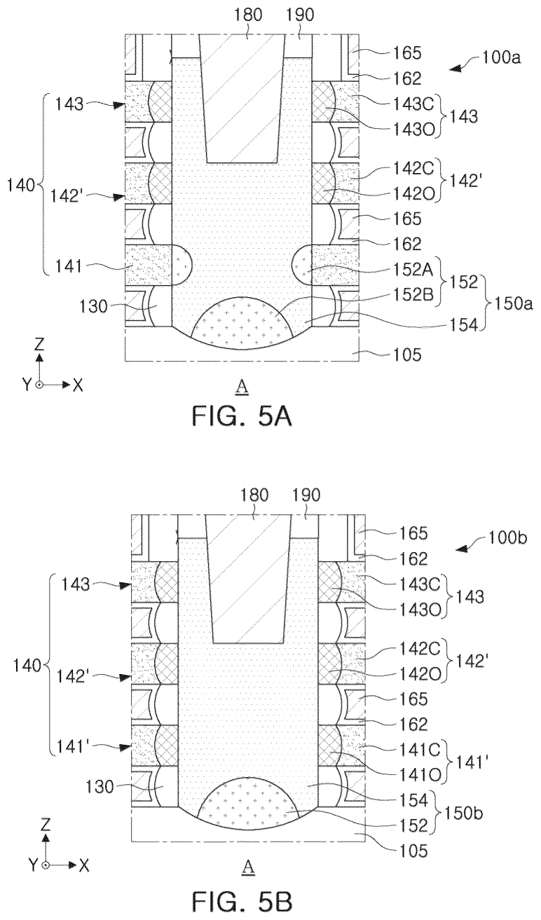

FIG. 3 is a partially enlarged view illustrating a portion of a semiconductor device according to example embodiments. FIG. 3 is an enlarged view of region “A” of FIG. 2.

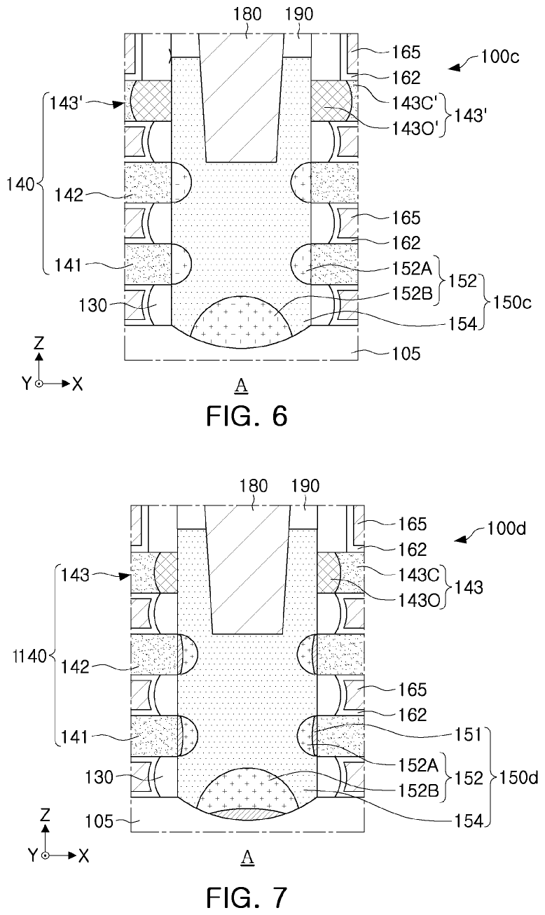

FIG. 4 is a diagram illustrating a distribution of an impurity concentration in a source/drain region in a semiconductor device according to example embodiments. FIG. 4 is a schematic diagram illustrating a profile of impurities in the source/drain region 150 along line B-B′ of FIG. 3.

Referring to FIG. 3, as the third semiconductor layer 143 includes the outer region 143O, the first epitaxial layer 152 is not disposed on the outer surface of the third semiconductor layer 143 of the example embodiment and may be disposed on the outer surfaces of the first and second semiconductor layers 141 and 142, though example embodiments are not limited thereto. Accordingly, an impurity concentration of a region contacting the third semiconductor layer 143, the upper semiconductor layer, of the source/drain region 150 and an impurity concentration of a region contacting the first and second semiconductor layers 141 and 142, the lower semiconductor layers, of the source/drain region 150 may be different from each other.

FIG. 4 illustrates an example of a profile in which the first and second epitaxial layers 152 and 154 include the same impurities. However, even when the first and second epitaxial layers 152 and 154 include different impurities, a profile having a concentration difference, similar to that of FIG. 4, may be illustrated. That is, in an example embodiment, the first and second epitaxial layers 152 and 154 may include different impurities and have a concentration profile as shown in FIG. 4.

In FIG. 4, a first section L1 is a region corresponding to the first epitaxial layers 152 of the source/drain region 150, and a second section L2 is a region corresponding to the second epitaxial layer 154 of the source/drain region 150. In addition, the first section L1 may be a region corresponding to an outer side of at least a portion of the first and second semiconductor layers 141 and 142, and the second section L2 may include a region corresponding to an outer side of the inner spacer layers 130 and the third semiconductor layer 143.

As illustrated in FIG. 4, the first epitaxial layers 152 may include impurities at a first concentration C1, and the second epitaxial layer 154 may include impurities at a second concentration C2, higher than the first concentration C1. The first and second concentrations C1 and C2 may be maximum concentrations of the first and second sections L1 and L2, respectively. The second concentration C2 may be, for example, about 10 times to about 20 times the first concentration C1, but example embodiments are not limited thereto. As described above, the source/drain region 150 may have profiles having different concentrations, which alternately appear on an outer side of the inner spacer layers 130 and the first to third semiconductor layers 141, 142, and 143 in a Z-direction, so that the first and second sections L1 and L2 may be recognized to be distinguished from each other.

According to example embodiments, a change in concentration of impurities in a boundary between the first and second sections L1 and L2 may be higher or lower. In addition, in each of the sections L1 and L2, a section in which the concentration of impurities is constant or uniform may appear. According to example embodiments, a peak of an impurity concentration may appear in each of the sections L1 and L2. A maximum concentration of impurities in the second layer 152B may also be the first concentration C1.

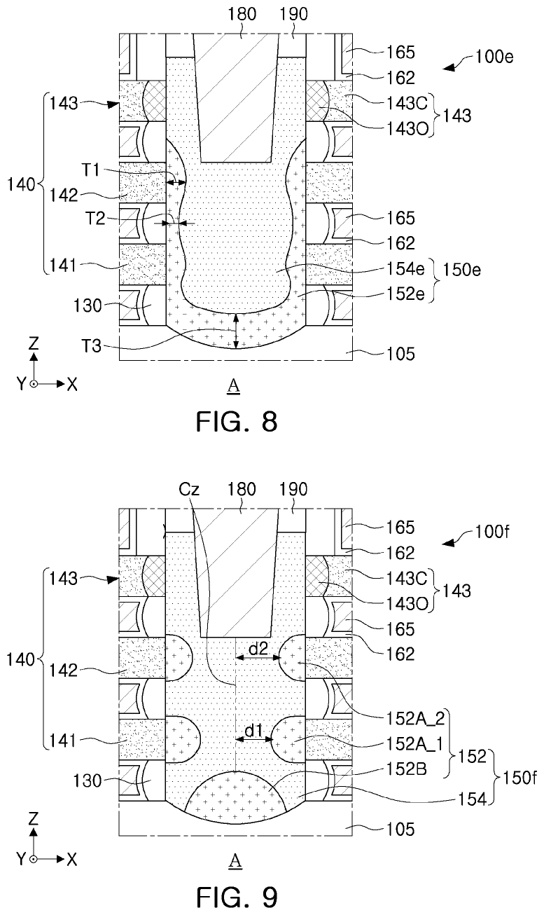

FIGS. 5A and 5B are partially enlarged views illustrating a portion of a semiconductor device according to example embodiments. FIGS. 5A and 5B are an enlarged view of region “A” of FIG. 2.

Referring to FIG. 5A, in a semiconductor device 100a, first epitaxial layers 152 may include first layers 152A, disposed on side surfaces of a first semiconductor layer 141, and a second layer 152B disposed on an upper surface of an active region 105. In an example embodiment, the first epitaxial layers 152 are not be disposed on side surfaces of a second semiconductor layer 142′, though example embodiments are not limited thereto.

In the present example embodiment, each of the second and third semiconductor layers 142 and 143 may be referred to as an “upper semiconductor layer,” and the first semiconductor layer 141 may be referred to as a “lower semiconductor layer.”

The second semiconductor layer 142′ may include a central region 142C and an outer region 1420 disposed on an outer side of a central region 142C in an X-direction. Similarly to the outer region 143O of the third semiconductor layer 143, the outer region 1420 of the second semiconductor layer 142′ may have a shape convex toward the central region 142C, may have crystallinity, lower than crystallinity of the central region 142C, or may include impurities, different from impurities included in the central region 142C.

Referring to FIG. 5B, in a semiconductor device 100b, first epitaxial layers 152 may be disposed on an upper surface of an active region 105 and is not disposed on side surfaces of a plurality of semiconductor layers 141, 142, and 143, though example embodiments are not limited thereto.

A first semiconductor layer 141′ may include a central region 141C and an outer region 1410 disposed on an outer side of the central region 141C in an X-direction. Similarly to the outer region 143O of the third semiconductor layer 143, the outer region 1410 of the first semiconductor layer 141′ may have a shape convex toward the central region 141C, may have crystallinity, lower than crystallinity of the central region 141C, or may include impurities, different from impurities included in the central region 141C.

This may be because, referring to FIG. 10G, an amorphous region is formed in a portion of the first semiconductor layer 141′ and/or a second semiconductor layer 142′ together with a third semiconductor layer 143 according to conditions of an ion implantation process.

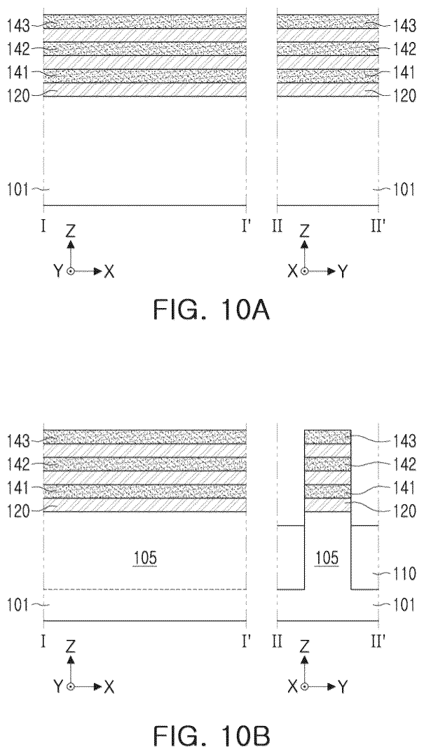

FIG. 6 is a partially enlarged view illustrating a portion of a semiconductor device according to example embodiments. FIG. 6 is an enlarged view of a region corresponding to region “A” of FIG. 2.

Referring to FIG. 6, in a semiconductor device 100c, an outer region 143O′ of a third semiconductor layer 143′ may extend from an outer surface, coplanar with outer surfaces of the inner spacers 130, to a relatively great depth as compared with that illustrated in FIG. 2. In example embodiments, the outer region 143O′ may overlap an entire inner spacer layers 130 in a Z-direction. In addition, an outer region 143O′ may overlap a gate dielectric layer 162 or a gate electrode 165 in the Z-direction. According to example embodiments, the outer region 143O′ may extend by a relatively small depth as compared with that illustrated in FIG. 2 to extend to a smaller depth than the inner spacer layers 130. For example, the outer region 143O′ may be adjusted to have various depths depending on process conditions.

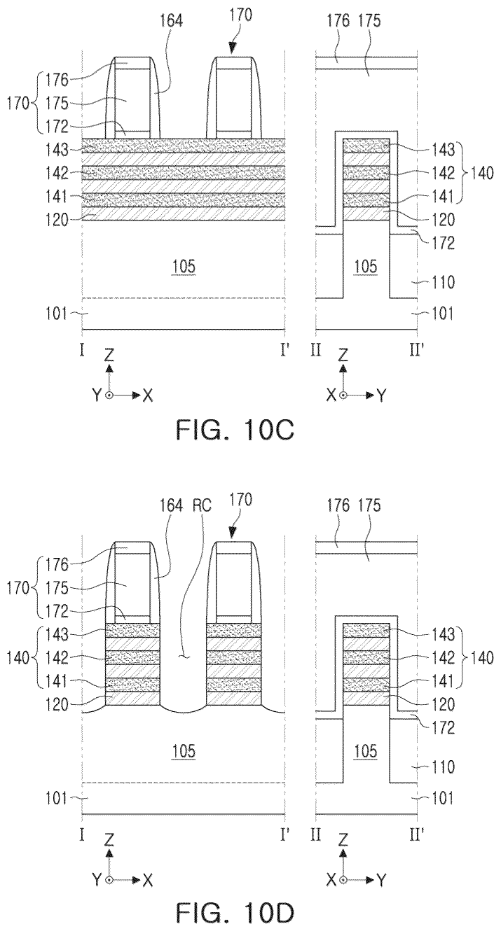

FIG. 7 is a partially enlarged view illustrating a portion of a semiconductor device according to example embodiments. FIG. 7 is an enlarged view of a region corresponding to region “A” of FIG. 2.

Referring to FIG. 7, in a semiconductor device 100d, a source/drain region 150d may include first epitaxial layers 152 and a second epitaxial layer filling a space between the first epitaxial layers 152, and may further include third epitaxial layers 151 disposed to contact the first epitaxial layers 152.

The third epitaxial layers 151 may be disposed on side surfaces of first and second semiconductor layers 141 and 142, respectively, and may be disposed on at least a portion of an upper surface of an active region 105 on a lower end of the source/drain region 150d. The third epitaxial layers 151 may be provided to promote growth of the first epitaxial layers 152 or to reduce lattice mismatch. The third epitaxial layers 151 may be, for example, a SiAs layer, a SiP layer, a SiPC layer, a SiC layer, a SiPAs layer, or a SiGeP layer. The third epitaxial layers 151 may include impurities having a concentration, lower than a concentration of impurities of the first epitaxial layers 152 and the second epitaxial layers 154, or may not include impurities. According to example embodiments, the third epitaxial layers 151 may be disposed in only a portion of side surfaces of the first and second semiconductor layers 141 and 142. A size of a region, in which the third epitaxial layer 151 contacts an upper surface of the active region 105, may vary according to example embodiments.

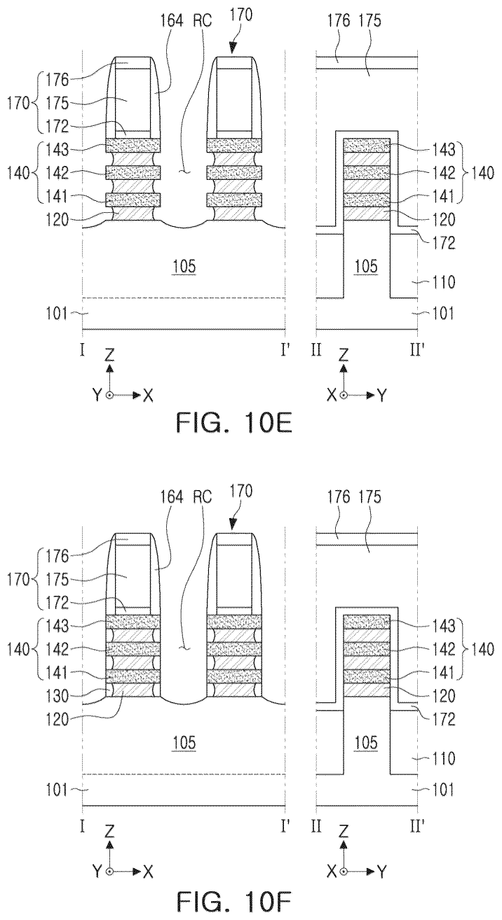

FIG. 8 is a partially enlarged view illustrating a portion of a semiconductor device according to example embodiments. FIG. 8 is an enlarged view of a region corresponding to region “A” of FIG. 2.

Referring to FIG. 8, in a semiconductor device 100e, a source/drain region 150e may have a form in which a first epitaxial layer 152e extends along side surfaces of first and second semiconductor layers 141 and 142 of a channel structure 140 and is disposed as a single layer while forming a lower surface of the source/drain region 150e on a lower end. The first epitaxial layer 152e may extend from a side surface of the second semiconductor layer 142 along a side surface of an inner spacer layers 130 on the second semiconductor layer 142, but may not extend to a side surface of a third semiconductor layer 143.

In example embodiments, a thickness of the first epitaxial layer 152e may be not uniform. The first epitaxial layer 152e may have a first maximum thickness T1 on sidewalls of the first and second semiconductor layers 141 and 142 and a second maximum thickness T2, lower than a first maximum thickness T1, on sidewalls of an inner spacer layers 130, and may have curvatures caused by the first and second maximum thicknesses T1 and T2. Such a structure may be controlled depending on a growth direction and a growth thickness of the first epitaxial layer 152e. In addition, a shape of a lower surface of the source/drain region 150e may have a downwardly convex shape of varying degrees according to example embodiments. Thus, a shape of the first epitaxial layer 152e may also vary on the lower surface of the source/drain region 150e. In example embodiments, the first epitaxial layer 152e may have a third maximum thickness T3, higher than the first maximum thickness T1, in a lower portion thereof.

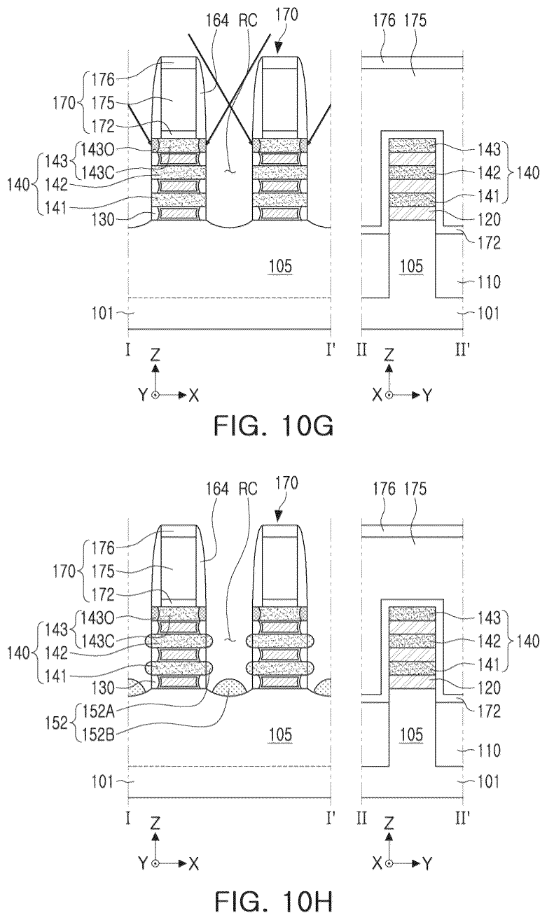

FIG. 9 is a partially enlarged view illustrating a portion of a semiconductor device according to example embodiments. FIG. 9 is an enlarged view of a region corresponding to region “A” of FIG. 2.

Referring to FIG. 9, in a semiconductor device 100f, first epitaxial layers 152 may have a structure, different from that of FIG. 2. First layers 152A_1 and 152A_2 of the first epitaxial layers 152 may include a first lower layer 152A_1, disposed on opposite side surfaces of the first semiconductor layer 141, and a first upper layer 152A_2 disposed on opposite side surface of the second semiconductor layer 142. The first lower layer 152A_1 may contact a side surface of the first semiconductor layer 141, and the first upper layer 152A_2 may contact a side surface of the second semiconductor layer 142.

The first lower layer 152A_1 may include a portion extending from a side surface of the first semiconductor layer 141 along an outer surface of an adjacent inner spacer layers 130, and the first upper layer 152A_2 may include a portion extending from a side surface of the semiconductor layer 142 along an outer surface of an adjacent inner spacer layers 130.

In example embodiments, a first distance d1 from a vertical central axis Cz of the source/drain region 150 to the first lower layer 152A_1 in an X-direction may be smaller than a second distance d2 from the vertical central axis Cz to the first upper layer 152A_2 in the X-direction. This may be because the first lower layer 152A_1 has a relatively larger volume than that of the first upper layer 152A_2.

FIGS. 10A to 10K are diagrams illustrating a process sequence of a method of fabricating a semiconductor device according to example embodiments. FIGS. 10A to 10K illustrate an example of a method of fabricating the semiconductor device of FIGS. 1 to 4, and illustrate cross-sections corresponding to FIG. 2.

Referring to FIG. 10A, sacrificial layers 120 and semiconductor layers 141, 142, and 143 may be alternately stacked on a substrate 101.

Sacrificial layers 120 may be replaced with a gate dielectric layer 162 and a gate electrode 165 through a subsequent process, as illustrated in FIG. 2. The sacrificial layers 120 may be formed of a material having etching selectivity with respect to semiconductor layers 141, 142, and 143. The semiconductor layers 141, 142, and 143 may include a material, different from a material of the sacrificial layers 120. The sacrificial layers 120 and the semiconductor layers 141, 142, and 143 may include, for example, a semiconductor material including at least one of silicon (Si), silicon-germanium (SiGe), and germanium (Ge), and may include different materials. In addition, the sacrificial layers 120 and the semiconductor layers 141, 142, and 143 may include or may not include impurities. For example, the sacrificial layers 120 may include silicon-germanium (SiGe), and the semiconductor layers 141, 142, and 143 may include silicon (Si).

The sacrificial layers 120 and the semiconductor layers 141, 142, and 143 may be formed by performing an epitaxial growth process using the substrate 101 as a seed. Each of the sacrificial layers 120 and the semiconductor layers 141, 142, and 143 may have a thickness ranging from about 1 angstrom (A) to 100 nanometers (nm). The number of the semiconductor layers 141, 142, and 143, stacked alternately with the sacrificial layers 120, may vary according to example embodiments.

Referring to FIG. 10B, a stack structure of the sacrificial layers 120 and the semiconductor layers 141, 142, and 143 and a portion of the substrate 101 may be removed to form active structures.

The active structure may include sacrificial layers 120 and semiconductor layers 141, 142, and 143 stacked alternately with each other, and may further include an active region 105 formed to protrude to an upper surface of the substrate 101 by removing a portion of the substrate 101. The active structures may be formed to have a line shape extending in one direction, for example, an X-direction, and may be disposed to be spaced apart from each other in a Y-direction.

An isolation layers 110 may be formed by filling a region, in which a portion of the substrate 101 is removed, with an insulating material and the recessing the region such that the active region 105 protrudes. Upper surfaces of the device isolation layers 110 may be formed to be lower than an upper surface of the active region 105.

Referring to FIG. 10C, sacrificial gate structures 170 and gate spacer layers 164 may be formed on the active structures.

The sacrificial gate structures 170 may be formed in a region, in which the gate dielectric layer 162 and the gate electrode 165 are disposed, on the channel structures 140 through a subsequent process, as illustrated in FIG. 2. The sacrificial gate structure 170 may include first and second sacrificial gate layers 172 and 175 and a mask pattern layer 176 stacked sequentially. The first and second sacrificial gate layers 172 and 175 may be patterned using a mask pattern layer 176. The first and second sacrificial gate layers 172 and 175 may be an insulating layer and a conductive layer, respectively. However, example embodiments are not limited thereto, and the first and second sacrificial gate layers 172 and 175 may be provided as a single layer. For example, the first sacrificial gate layer 172 may include a silicon oxide, and the second sacrificial gate layer 175 may include polysilicon. The mask pattern layer 176 may include a silicon oxide and/or a silicon nitride. The sacrificial gate structures 170 may have a line shape extending in one direction to intersect the active structures. The sacrificial gate structures 170 may extend, for example, in a Y-direction and may be disposed to be spaced apart from each other in an X-direction.

Gate spacer layers 164 may be formed on opposite sidewalls of the sacrificial gate structures 170. The gate spacer layers 164 may be formed by forming a layer having a uniform thickness along upper and side surfaces of the sacrificial gate structures 170 and the active structures and then anisotropically etching the layer. The gate spacer layers 164 may be formed of a low-κ material, and may include at least one of, for example, SiO, SiN, SiCN, SiOC, SiON, or SiOCN.

Referring to FIG. 10D, the exposed sacrificial layers 120 and exposed the semiconductor layers 141, 142, and 143 may be removed to form a recess region RC between the sacrificial gate structures 170, and thus channel structures 140 may be formed.

The exposed sacrificial layers 120 and the exposed semiconductor layers 141, 142, and 143 may be removed using the sacrificial gate structures 170 and the gate spacer layers 164 as masks. Accordingly, the semiconductor layers 141, 142, and 143 may each have a limited length in the X-direction and may constitute the channel structure 140.

Referring to FIG. 10E, a portion of the exposed sacrificial layers 120 may be removed from a side surface thereof.

The sacrificial layers 120 may be selectively etched with respect to the channel structures 140 by, for example, a wet etching process to be removed to a predetermined depth from the side surface thereof along an X-direction. Due to the above-described lateral etching, the sacrificial layers 120 may have inwardly concave side surfaces. However, a shape of the side surfaces of the sacrificial layers 120 is not limited to that illustrated in the drawing.

Referring to FIG. 10F, inner spacer layers 130 may be formed in a region in which the sacrificial layers 120 are removed.

The inner spacer layers 130 may be formed by filling the region, in which the sacrificial layers 120 are removed, with an insulating material and removing the insulating material deposited on an outer side of the channel structures 140. The inner spacer layers 130 may be formed of the same material as the spacer layers 164, but example embodiments are not limited thereto. The inner spacer layers 130 may include at least one of, for example, SiN, SiCN, SiOCN, SiBCN, or SiBN.

Referring to FIG. 10G, an ion implantation process may be performed to a portion of the third semiconductor layer 143.

The portion of the third semiconductor 143 may be an outer region 143O. The outer region 143O may be a region in which a portion of the third semiconductor layer 143 are amorphized by the ion implantation process. In the third semiconductor layer 143, a remaining portion which is not amorphized by the ion implantation process may be referred to as a central region 143C. The outer region 143O may be disposed on an outer side of the central region 143C in an X-direction.

The ion implantation process may be performed using at least one source of silicon (Si), phosphorus (P), or arsenic (As). The ion implantation process may cause an impurity concentration of the central region 143C to be different from an impurity concentration of the outer region 143O.

In example embodiments, only a portion of the third semiconductor layer 143 may be amorphized by the ion implantation process due to the aspect ratio of the sacrificial gate structures 170. According to example embodiments, even a portion of the second semiconductor layer 142 or the first semiconductor layer 141 may also be amorphized by the ion implantation process, and thus the semiconductor devices 100a and 100b of FIG. 5A or 5B may be fabricated.

In the present operation, by adjusting process conditions such as a process time of the ion implantation process, a size of the outer region 143O may be adjusted as in the semiconductor device 100c illustrated in in FIG. 6.

Referring to FIG. 10H, first epitaxial layers 152 may be formed in the recess region RC.

The first epitaxial layers 152 may be formed by epitaxial growth on sidewalls of the first and second semiconductor layers 141 and 142 and an upper surface of the active region 105 exposed by the recess region RC, and may include impurities through in-situ doping. The first epitaxial layers 152 may be, for example, a SiAs layer, a SiP layer, a SiPC layer, a SiC layer, a SiPAs layer, or a SiGeP layer. First layers 152A of the first epitaxial layers 152 may be formed on side surfaces of the first and second semiconductor layers 141 and 142, and the second layer 152B may be formed on the active region 105 on the bottom surface of the recess region RC. The first layers 152A may be formed to have surfaces, convex outwardly from side surfaces of the first and second semiconductor layers 141 and 142, but example embodiments are not limited thereto. The second layer 152B may be formed to have a surface, upwardly convex from a bottom surface of the recess region RC, on the surface of the active region 105, but example embodiments are not limited thereto.

As the third semiconductor layer 143 includes the outer region 143O amorphized by the ion implantation process, the first epitaxial layer 152 is not be formed on a side surface of the third semiconductor layer 143 in the example embodiment, though example embodiments are not limited thereto. For example, the outer region 143O may suppress the epitaxial growth of the first epitaxial layer 152. Accordingly, the first layers 152A may be formed on only side surfaces of the first and second semiconductor layers 141 and 142.

Referring to FIG. 10I, a second epitaxial layer 154 may be formed to fill the recess region RC.

The second epitaxial layer 154 may be grown from the first epitaxial layers 152 and the active region 105 using a selective epitaxial growth (SEG) process, and may be a semiconductor layer doped in-situ, for example, a SiP layer. A concentration of phosphorus (P) in the second epitaxial layer 154 may be higher than a concentration of arsenic (As) or phosphorus (P) in the first epitaxial layers 152. Accordingly, a source/drain region 150 may be finally formed.

The second epitaxial layer 154 may be formed to fill a space between the first epitaxial layers 152 vertically disposed in a Z-direction and to fill a space between the first epitaxial layers 152 disposed on opposite side surfaces of the recess region RC in an X-direction.

The second epitaxial layer 154 may have a shape, similar to an ellipse, together with the first epitaxial layer 152, and may have a relatively planar upper surface. This may be because the first epitaxial layer 152, a seed layer of the SEG process, is not formed on the third semiconductor layer to suppress overgrowth of the second epitaxial layer. Accordingly, the semiconductor device 100 (see FIG. 2) having improved productivity and electrical characteristics may be provided.

In the source/drain region 150, both the first and second epitaxial layers 152 and 154 may be epitaxially grown to be formed. Accordingly, a boundary between each of the first epitaxial layers 152 and each of the second epitaxial layers 154 in the finally formed source/drain region 150 may not be identified on a microscope image. Even in this case, the first and second epitaxial layers 152 and 154 are formed of materials having different compositions, so that a boundary therebetween may be substantially classified by analysis such as a Transmission Electron Microscopy Energy Dispersive X-ray (TEM-EDX) spectroscopy, or the like.

Referring to FIG. 10J, an interlayer insulating layer 190 may be formed, and the sacrificial layers 120 and the sacrificial gate structures 170 may be removed.

The interlayer insulating layer 190 may be formed by forming an insulating layer to cover the sacrificial gate structures 170 and the source/drain regions 150 and performing a planarization process.

The sacrificial layers 120 and the sacrificial gate structures 170 may be selectively removed with respect to the gate spacer layers 164, the interlayer insulating layer 190, and the channel structures 140. The sacrificial gate structures 170 may be removed to form upper gap regions UR, and the sacrificial layers 120 exposed through the upper gap regions UR may then be removed to form lower gap regions LR. For example, when the sacrificial layers 120 include silicon-germanium (SiGe) and the channel structures 140 include silicon (Si), the sacrificial layers 120 may be selectively removed by performing a wet etching process using peracetic acid as an etchant. During the removal process, the source/drain regions 150a may be protected by the interlayer insulating layer 190 and the inner spacer layers 130.

Referring to FIG. 10K, gate structures 160 may be formed in the upper gap regions UR and the lower gap regions LR.

The gate dielectric layers 162 may be formed to conformally cover inner surfaces of the upper gap regions UR and the lower gap regions LR. The gate electrodes 165 may be formed to completely fill the upper gap regions UR and the lower gap regions LR, and may then be removed from upper portions thereof to a predetermined depth in the upper gap regions UR. A gate capping layer 166 may be formed in a region in which the gate electrodes 165 are removed in the upper gap regions UR. Accordingly, gate structures 160 including the gate dielectric layer 162, the gate electrode 165, the gate spacer layers 164, and the gate capping layer 166 may be formed.

Referring to FIG. 2 together, a contact plug 180 may be formed.

The interlayer insulating layer 190 may be patterned to form a contact hole, and the contact hole may then be filled with a conductive material to form the contact plug 180. A lower surface of the contact hole may be recessed into the source/drain regions 150a or may have curves along upper surfaces of the source/drain regions 150. A shape and disposition of the contact plug 180 may vary according to example embodiments.

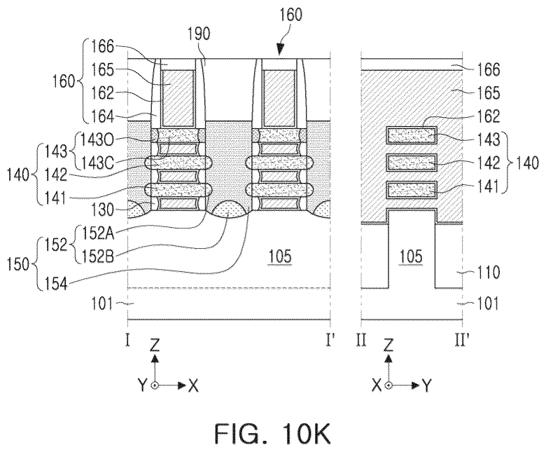

FIG. 11 is a block diagram illustrating an electronic apparatus including a semiconductor device according to example embodiments.

Referring to FIG. 11, an electronic apparatus 1000 according to example embodiments may include a communications unit 1010, an input unit 1020, an output unit 1030, a memory 1040, and a processor 1050.

The communications unit 1010 may include a wired/wireless communications module, for example, a wireless internet module, a short-range communications module, a GPS module, or a mobile communications module. The wired/wireless communications module included in the communications unit 1010 may be connected to an external communications network by various communications standards to transmit and receive data.

The input unit 1020 is a module provided for a user to control operations of the electronic apparatus 1000, and may include a mechanical switch, a touchscreen, a voice recognition module, or the like. In addition, the input unit 1020 may include a mouse operating based on a track ball or a laser pointer, or a finger mouse, and may further include various sensor modules enabling a user to input data.

The output unit 1030 may output information, processed by the electronic apparatus 1000, in an audio or video format. The memory 1040 may store a program for processing or controlling the processor 1050, data, or the like. The processor 1050 may transmit an instruction to the memory 1040 depending on a required operation to store data therein or read data therefrom.

The memory 1040 may be embedded in the electronic apparatus 1000, or may communicate with the processor 1050 via an additional interface. When the memory 1040 communicates with the processor 1050 via the additional interface, the processor 1050 may store data in, or read data from, the memory 1040 using various interface standards such as secure digital (SD), secure digital high capacity (SDHC), secure digital extended capacity (SDXC), MICRO SD, universal serial bus (USB), or the like.

The processor 1050 may control operations of each unit included in the electronic apparatus 1000. The processor 1050 may perform controlling or processing operations related to voice calls, video calls, or data communications, or may controlling and processing operations for multimedia playback and management. The processor 1050 may process an input transmitted from a user via the input unit 1020, and may output a result thereof via the output unit 1030. In addition, the processor 1050 may write data, required to control operations of the electronic apparatus 1000, to the memory 1040, or read data from the memory 1040, as described above. At least one of the processor 1050 and the memory 1040 may include the semiconductor device according to the various example embodiments described above with reference to FIGS. 1 to 9.

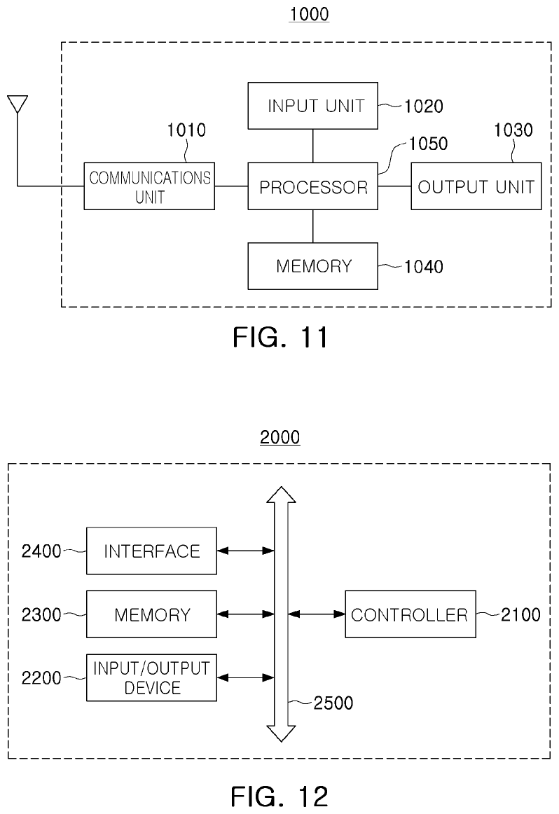

FIG. 12 is a schematic diagram illustrating a system including a semiconductor device according to example embodiments.

Referring to FIG. 12, a system 2000 may include a controller 2100, an input/output device 2200, a memory 2300, and an interface 2400. The system 2000 may be a mobile system or a system transmitting or receiving information. The mobile system may be a portable digital assistant (PDA), a portable computer, a web tablet PC, a wireless phone, a mobile phone, a digital music player, or a memory card.

The controller 2100 may serve to execute a program or to control the system 2000. The controller 2100 may be a microprocessor, a digital signal processor, a microcontroller, or the like.

The input/output device 2200 may be used to input or output data of the system 2000. The system 2000 may be connected to an external device, for example, a personal computer or a network to exchange data with the external device using the input/output device 2200. The input/output device 2200 may be, for example, a keypad, a keyboard, or a display.

The memory 2300 may store code and/or data for an operation of the controller 2100, and/or data processed by the controller 2100.

The interface 2400 may be a data transmission path between the system 2000 and an external device. The controller 2100, the input/output device 2200, the memory 2300, and the interface 2400 may communicate with each other through a bus 2500.

At least one of the controller 2100 and the memory 2300 may include the semiconductor device according to the various example embodiments described above with reference to FIGS. 1 to 9.

As described above with respect to various example embodiments of a semiconductor device, an outer region may be formed in at least a portion of a plurality of semiconductor layers to suppress growth of a first epitaxial layer, and thus a semiconductor device having improved electrical characteristics may be provided.

While example embodiments have been particularly shown and described above, it will be understood that various changes in form and details may be made therein without departing from the spirit and scope of the following claims.

1. A semiconductor device comprising:
a substrate;
an active region extending in a first direction on the substrate;
a plurality of semiconductor layers spaced apart from each other in a vertical direction on the active region, the plurality of semiconductor layers comprising a lower semiconductor layer and an upper semiconductor layer on the lower semiconductor layer;
a gate structure extending in a second direction on the substrate and intersecting the active region and the plurality of semiconductor layers, the gate structure surrounding the plurality of semiconductor layers; and
a source/drain region provided on the active region on at least one side adjacent to the gate structure and contacting the plurality of semiconductor layers,
wherein the source/drain region comprises first epitaxial layers and a second epitaxial layer,
wherein the first epitaxial layers comprise a first layer contacting a side surface of the lower semiconductor layer in the first direction, and a second layer provided on and contacting the active region,
wherein the second epitaxial layer contacts a side surface of the upper semiconductor layer in the first direction, and
wherein the first layer is between the second epitaxial layer and the side surface of the lower semiconductor layer.

2. The semiconductor device of claim 1, wherein each of the first epitaxial layers has a first impurity concentration, and
wherein the second epitaxial layer has a second impurity concentration that is higher than the first impurity concentration.

3. The semiconductor device of claim 1, further comprising:
inner spacer layers provided on opposite sides adjacent to the gate structure in the first direction on a lower surface of each of the plurality of semiconductor layers and vertically overlapping the plurality of semiconductor layers.

4. The semiconductor device of claim 3, wherein the first layer protrudes more towards the second epitaxial layer as compared to the inner spacer layers.

5. The semiconductor device of claim 1, wherein at least a portion of the first layer of the first epitaxial layers vertically overlaps the second epitaxial layer.

6. The semiconductor device of claim 1, wherein the upper semiconductor layer has a central region and an outer region on an outer side of the central region in the first direction, and the outer region is different from the central region.

7. The semiconductor device of claim 6, wherein the central region lacks impurities, and
wherein the outer region comprises impurities.

8. The semiconductor device of claim 7, wherein the impurities in the outer region comprise at least one of silicon (Si), phosphorus (P), or arsenic (As).

9. The semiconductor device of claim 6, wherein a material of the outer region has a crystallinity that is lower than a crystallinity of a material of the central region.

10. The semiconductor device of claim 9, wherein the material of the central region comprises single-crystalline silicon, and
wherein the material of the outer region comprises amorphous silicon.

11. The semiconductor device of claim 6, wherein the outer region has a shape that is convex toward the central region.

12. The semiconductor device of claim 1, wherein the lower semiconductor layer comprises a first semiconductor layer and a second semiconductor layer stacked on the first semiconductor layer,
wherein the first layer comprises a first lower layer contacting a side surface of the first semiconductor layer, and a first upper layer contacting a side surface of the second semiconductor layer, and
wherein a first distance from a vertical central axis of the source/drain region in the first direction to the first lower layer is smaller than a second distance from the vertical central axis to the first upper layer.

13. A semiconductor device comprising:
a substrate;
an active region extending in a first direction on the substrate;
a plurality of semiconductor layers spaced apart from each other in a vertical direction on the active region;
a gate structure extending in a second direction on the substrate and intersecting the active region and the plurality of semiconductor layers, the gate structure surrounding the plurality of semiconductor layers;
inner spacer layers provided on opposite sides adjacent to the gate structure in the first direction on a lower surface of each of the plurality of semiconductor layers and vertically overlapping the plurality of semiconductor layers; and
a source/drain region provided on the active region on at least one side adjacent to the gate structure and contacting the plurality of semiconductor layers,
wherein the plurality of semiconductor layers comprise a lower semiconductor layer and an upper semiconductor layer provided on the lower semiconductor layer, and
wherein the source/drain region comprises:
a first epitaxial layer provided on a side surface of the lower semiconductor layer and at a level lower than a level of the upper semiconductor layer; and
a second epitaxial layer having a composition that is different from a composition of the first epitaxial layer, extending upwardly on a side surface of the upper semiconductor layer and covering the first epitaxial layer.

14. The semiconductor device of claim 13, wherein the second epitaxial layer covers a first side surface formed by the inner spacer layers and the upper semiconductor layer, and a second side surface formed by the first epitaxial layer protruding from the lower semiconductor layer.

15. The semiconductor device of claim 13, wherein the source/drain region further comprises a third epitaxial layer between the first epitaxial layer and the lower semiconductor layer.

16. The semiconductor device of claim 13, wherein a portion of the first epitaxial layer extends along outer surfaces of the inner spacer layers.

17. A semiconductor device comprising:
a substrate;
an active region extending in a first direction on the substrate;
a plurality of semiconductor layers spaced apart from each other in a vertical direction on the active region, the plurality of semiconductor layers comprising a lower semiconductor layer and an upper semiconductor layer;
a gate structure extending in a second direction on the substrate and intersecting the active region and the plurality of semiconductor layers, the gate structure surrounding the plurality of semiconductor layers; and
a source/drain region provided on the active region on at least one side adjacent to the gate structure and contacting the plurality of semiconductor layers,
wherein the upper semiconductor layer has a central region and an outer region on an outer side of the central region in the first direction, and
wherein the outer region is different from the central region.

18. The semiconductor device of claim 17, wherein the central region comprises first impurities and the outer region comprises second impurities that are different from the first impurities.

19. The semiconductor device of claim 17, wherein a material of the outer region has a crystallinity that is lower than a crystallinity of a material of the central region.

20. The semiconductor device of claim 17, wherein an impurity concentration of a region of the source/drain region contacting the upper semiconductor layer is higher than an impurity concentration of a region of the source/drain region contacting the lower semiconductor layer.
